(19) United States
(12) Patent Application Publication
(10) Pub. No.: US 2008/0191727 A1
(43) Pub. Date: Aug. 14, 2008

(54) PROBE AND PROBE ASSEMBLY

(75) Inventors: Yuko YAMADA, Aomori (JP); Hideki HIRAKAWA, Aomori (JP); Masahisa TAZAWA, Aomori (JP); Takayuki HAYASHIZAKI, Aomori (JP)

Correspondence Address: INGRASSIA FISHER & LORENZ, P.C., 7010 E. COCHISE ROAD, SCOTTSDALE, AZ, 85253, US

(73) Assignee: KABUSHIKI KAISHA NIHON MICRONICS, Tokyo (JP)

(21) Appl. No.: 12/017,295

(22) Filed: Jan. 21, 2008

(30) Foreign Application Priority Data
Feb. 9, 2007 (JP) 2007-031094

(51) Int. Cl. G01R 1/067

(52) U.S. Cl. 324/762

(57) ABSTRACT

The present invention provides a probe in which electrical short-circuit between the probes adjacent to each other is reliably prevented and that is manufactured relatively easily. The present invention provides a probe comprising a probe main body made of a plate-shaped member having an attachment region having an attachment end portion and extending in a direction distanced from the attachment end portion, an arm region continuing into the attachment region and extending in a direction intersecting with the extending direction of the attachment region, and a probe tip region intersecting with the longitudinal direction of the arm region, extending from the arm region to the opposite side of a side where the attachment end portion of the attachment region is located, seen from the arm portion, and having a probe tip at its extending end portion. On at least one surface of the probe is formed an insulating film made of a photosensitive electrically insulating material that exposes the attachment end portion of the attachment region.

### BACKGROUND OF THE INVENTION

The present invention relates to a probe suitable for use in an electrical test of a plurality of semiconductor integrated circuits formed on a semiconductor wafer and a prove assembly to which this probe has been provided.

In an electrical test to determine whether or not a device under test such as an electronic circuit is manufactured in accordance with the specification, a probe assembly is used. The probe assembly has a plurality of contactors (probes). As the probes are connected to electrodes of the device under test, the device under test is electrically connected to a tester main body, and an electrical test is performed.

In a case where the device under test is a large-sized plate-shaped product such as a liquid crystal display panel, an elongated plate-shaped blade-type probe is used as a contactor (for example, refer to Patent Document 1). A plurality of such blade-type probes are layered with insulating ceramic plates inbetween and are integrated with one another by insulating resin coating formed by injection molding to cover the center portion of each probe so as to expose the probe tip formed at one end of each probe. Thus, short-circuit between the adjacent blade-type probes is prevented.

On the other hand, in the case of a plurality of semiconductor integrated circuits formed on a semiconductor wafer, they generally undergo the aforementioned electrical test before being separated into respective chips. In such a case, a cantilever-type probe made of a plate-shaped member is used as a contactor (for example, refer to Patent Document 2). This probe is a plate-shaped member formed in an entirely cranked flat surface shape constituted by an attachment region, an arm region continuing into the attachment region, and a probe tip region. The arm region is held on a probe board via the attachment region so as to be supported in a cantilevered manner. At the tip end portion of the arm region or the arm portion held in a cantilevered manner is formed the probe tip region, and a probe tip is formed at the tip end of the probe tip region.

In this cantilever-type probe, the tip end portion of the arm region at which the probe tip region is formed acts as a free end, and by elasticity of the arm region held in a cantilevered manner, the probe tip of the probe tip region is appropriately thrust to the device under test. However, a plurality of probes are arranged to be close to one another. Thus, when the arm portion or the arm region of each probe is deformed in a mutually approaching direction, short-circuit between the adjacent probes may occur even if the deformation is slight.

Moreover, in this cantilever-type probe, the arm region of each probe needs to be held so as to enable independent deformation in order to maintain the aforementioned elasticity of the arm region of each probe suitably. Thus, the plurality of probes cannot be integrated with one another at their arm regions by a resin material by injection molding as in the case of the blade-type probes. Then, one surface of each probe may be covered with an insulating layer made of a resin material to prevent short-circuit between the cantilever-type probes. However, if such a resin material spreads to the edge portion of the attachment region as an attachment end portion of the probe, it will prevent the probe from being fixed to the probe board with solder. Since the resin material needs to be applied to the plurality of cantilever-type micro probes with their edge portions of the attachment regions exposed, forming such an insulating layer on the plurality of micro probes is not easy.

Patent Document 1: Japanese Patent Appln. Public Disclosure No. 6-174750.

Patent Document 2: International Publication WO2006/075408 Pamphlet.

### BRIEF SUMMARY OF THE INVENTION

It is an object of the present invention to provide a cantilever-type probe and a probe assembly comprising the probe in which electrical short-circuit between the probes adjacent to each other is reliably prevented and that are manufactured relatively easily.

The present invention is characterized in that, basically on at least one surface of a probe main body made of a plate-shaped member having an attachment region having an attachment end portion and extending in a direction distanced from the attachment end portion, an arm region continuing into the attachment region and extending in a direction intersecting with the extending direction of the attachment region, and a probe tip region intersecting with the longitudinal direction of the arm region, extending from the arm region to the opposite side of a side where the attachment end portion of the attachment region is located, seen from the arm portion, and having a probe tip at its extending end portion, an insulating film formed to expose the attachment end portion of the attachment region is made of a photosensitive electrically insulating material.

According to the present invention, since the insulating film is made of a photosensitive electrically insulating material, the insulating film can be formed only at a necessary portion by applying the photosensitive electrically insulating material entirely to the probe or the probe main body including the probe tip and thereafter performing selective exposure and development with use of a mask. Thus, without formation of the insulating film at the attachment end portion, which will disturb application of the conductive adhesive such as Pb-fee solder if covered, the insulating film can be formed only at a necessary portion relatively easily and accurately.

The probe according to the present invention can adhere to a corresponding conductive path of a probe board at the attachment end portion of the probe main body via conductive adhesive such as Pb-free solder as a contactor of a probe assembly.

The insulating film made of a photosensitive electrically insulating material can be formed in relation to a probe manufacturing process. That is, a resist pattern having a recess corresponding to a flat surface shape of at least the probe main body is formed on a base table by using a photoresist, and a metal material for the probe is deposited in the recess. After deposition of the metal material for the probe main body, the photoresist is removed, and the photosensitive electrically insulating material is applied on all areas on the upper surface of the probe main body formed on the base table by, for example, a spin coat technique. Thereafter, the photosensitive electrically insulating material is selectively exposed with use of an exposure mask. Light is irradiated to an unnecessary portion in a case where the photosensitive electrically insulating material is positive, while light is irradiated to a necessary portion in a case where the photosensitive electrically insulating material is negative.

The photosensitive electrically insulating material also undergoes development processing after selective exposure. As a result, since the photosensitive electrically insulating material is left at least at the necessary portion as the insulating film and is removed from the rest or unnecessary portion containing the attachment end portion, the attachment end portion is exposed from the insulating film.

It is preferable that the insulating film is formed on one surface of the probe to cover the probe tip region.

According to the present invention, by forming the insulating film by the photosensitive electrically insulating material and performing selective exposure and development processing to it, the electrically insulating film that reliably covers a necessary portion for prevention of short-circuit and reliably exposes a portion that will disturb attachment if covered can be formed easily and reliably. Thus, it is possible to provide a probe and a probe assembly in which the adjacent probes do not electrically contact each other and that are manufactured relatively easily.

### BRIEF DESCRIPTION OF THE DRAWINGS

FIG. 1 is a schematic view partially showing a probe assembly according to the present invention.

FIG. 2 is an enlarged front view of a probe in the probe assembly shown in FIG. 1.

FIG. 3 is a partial bottom view of an array of the plurality of probes in the probe assembly shown in FIG. 1.

FIGS. 4 (a) to 4 (g) are process diagrams showing steps for manufacturing the probe according to the present invention.

### DESCRIPTION OF THE PREFERRED EMBODIMENTS

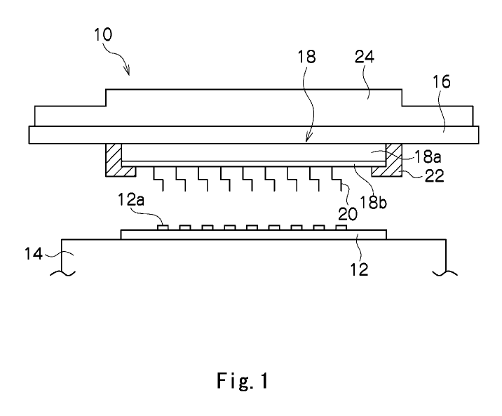

A probe assembly 10 according to the present invention is used for an electrical test of a plurality of integrated circuits (not shown) formed on a semiconductor wafer 12 as shown in FIG. 1. The semiconductor wafer 12 is removably held on a vacuum chuck 14, for example, with a plurality of electrodes 12a formed on its one surface directing upward. The probe assembly 10 is supported by a not shown frame member to be movable relatively to the vacuum chuck 14 in directions approaching and distanced from the semiconductor wafer 12 on the vacuum chuck 14 for the electrical test of the aforementioned integrated circuits of the semiconductor wafer 12 on the vacuum chuck 14.

The probe assembly 10 comprises a printed wiring board 16 and a probe board 18 piled up on the printed wiring board. The probe board 18 is a layered body consisting of a ceramic board 18a and a multi-layered wiring board 18b whose upper surface is connected to the ceramic board, as is conventionally well known. On the lower surface of the probe board 18, that is, the multi-layered wiring board 18b, are arranged and attached a plurality of probes 20 according to the present invention.

The probe board 18 is attached integrally with the printed wiring board 16 so as to be piled on the lower surface of the printed wiring board 16 via a conventionally well-known attachment ring assembly 22 made of a dielectric material such as a ceramic and not shown combining members similar to conventional ones such as bolts so that the probes 20 direct downward. In the example shown in the figure, on the upper surface of the printed wiring board 16 is integrally arranged a reinforcement member 24 that is made of a metal material and allows partial exposure of the aforementioned upper surface of the printed wiring board 16.

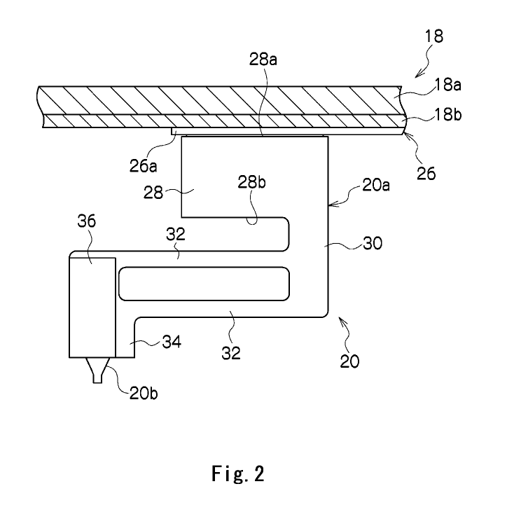

On the multi-layered wiring board 18b of the probe board 18 are formed conventionally well-known plural conductive paths 26 as shown in FIG. 2. The respective probes 20 are attached to the probe board 18 by being fixedly connected to probe lands 26a of the respective corresponding conductive paths 26.

The aforementioned conductive paths on the probe board 18 corresponding to the respective probes 20 are electrically connected to sockets (not shown) arranged in an area exposed from the reinforcement member 24 on the upper surface of the printed wiring board 16 via respective conductive paths (not shown) respectively penetrating the ceramic board 18a and the printed wiring board 16 as in a conventionally well-known manner and are connected to a circuit of a not shown tester main body via the sockets.

Accordingly, by letting the probe assembly 10 and the vacuum chuck 14 move so as to approach each other so that the respective probes 20 of the probe assembly 10 abut on the corresponding electrodes 12a on the semiconductor wafer 12 as a device under test, the electrodes 12a can be connected to the circuit of the aforementioned tester main body, and thus an electrical test of the device under test 12 can be performed.

Referring to FIG. 2, which is an enlarged view of each probe 20, each probe 20 comprises a plate-shaped probe main body 20a and a probe tip 20b part of which is buried in the probe main body. They exhibit relatively good conductivity.

The probe main body 20a may be made of a highly flexible metal material with relatively excellent flexibility such as nickel, a nickel alloy including, for example, a nickel-phosphorus alloy, a nickel-tungsten alloy, a nickel-cobalt alloy, and a nickel-chromium alloy, phosphor bronze, or a palladium-cobalt alloy. Also, the probe tip 20b may be made of a low contact resistance metal material with lower contact resistance to e.g., an aluminum electrode than that of the metal material for the probe main body 20a such as gold, silver, rhodium, platinum, palladium, or ruthenium, arbitrarily.

In the example shown in the figure, the probe main body 20a comprises an attachment region 28 whose flat surface shape is a rectangular shape, a strip-shaped connection region 30 extending downward from one side of the attachment region, arm regions 32, 32 extending in a lateral direction from the connection region, and a probe tip region 34 continuing into the arm regions. An upper edge 28a of the attachment region 28 is an attachment end portion to the probe land 26a. In the example shown in the figure, the arm regions 32 continue into the attachment region 28 extending downward from the upper edge or the attachment end portion 28a via the connection region 30.

The arm regions 32 extend in a lateral direction with a space from a lower edge 28b of the attachment region 28. In the example shown in the figure, the arm regions 32 are a pair of arm regions 32, 32 extending in parallel with each other to be distanced from each other in an up-down direction. The probe tip region 34 extends from the tip ends of the both arm regions to the opposite side of a side where the attachment end portion 28a is located, that is, to the lower side, so as to connect the both arm regions 32.

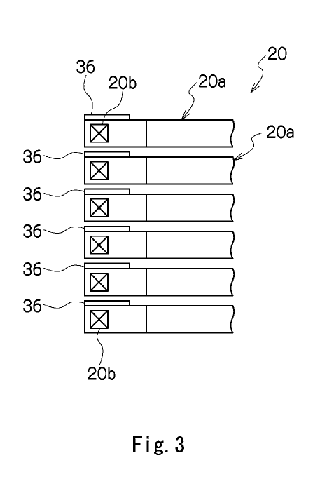

Each probe 20 is fixed to the probe land 26a of the conductive path 26 at the attachment end portion 28a of the probe main body 20a, and as shown in FIG. 3, the plurality of probes 20 are arranged in series to be close to one another with their probe tips 20b arrayed on a straight line. Thus, between the adjacent probes 20, the probe tip region 34 located on the free end side of the arm regions 32 is easy to cause displacement of the probe main body 20a in the thickness direction most likely, and thus mutual contact is easy to occur at the regions 34.

In the probe assembly 10 according to the present invention, in order to prevent electrical short-circuit between the adjacent probes 20, an insulating film 36 made of a photosensitive electrically insulating material such as photosensitive polyimide is formed on at least one surface of each of the probes adjacent to one another, as shown in FIGS. 2 and 3. In the example shown in the figure, the rectangular insulating film 36 is formed, to cover part of the probe tip region 34, on one surface out of a pair of opposed surfaces of the probe main bodies 20a opposed to each other between the adjacent probes 20. This insulating film 36 is provided between the adjacent probes 20 to reliably prevent electrical contact between them.

The probe 20 is fixed to the probe land 26a of the corresponding conductive path 26 at the attachment end portion 28a of the probe main body 20a, using conductive adhesive such as Pb-free solder. The insulating film 36 can be formed to cover desired areas except the attachment end portion 28a of the probe main body 20a so as not to disturb the solder.

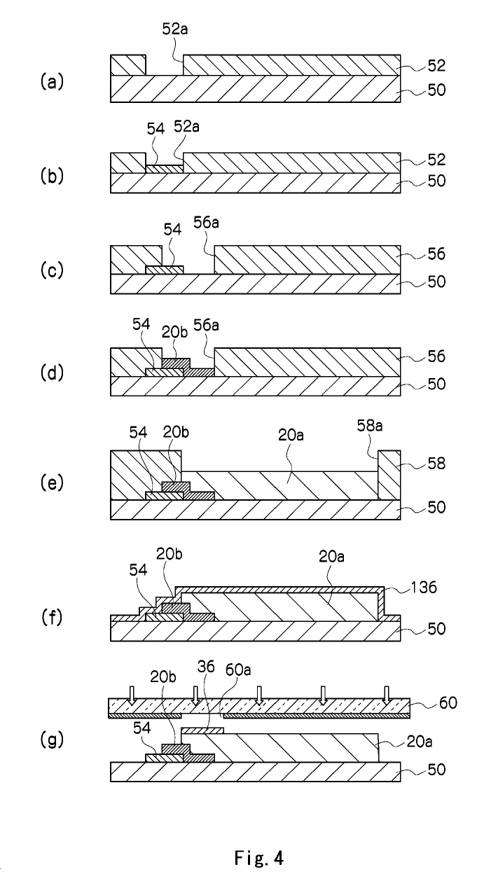

An example of a method for manufacturing the probe 20 according to the present invention is explained with reference to FIG. 4. As shown in FIG. 4 (a), a resist pattern having a recess 52a for a sacrificial layer is formed on a mirror-finished silicon crystal substrate 50, for example, by using a photoresist 52. This resist pattern can be formed by selectively exposing via a mask having a desired pattern the photoresist 52 uniformly applied on the silicon crystal substrate 50 by, for example, a spin coat technique, and thereafter developing the photoresist, as is conventionally well known in the photolithographic technique.

In the recess 52a is deposited a sacrificial layer material such as copper so as to have uniform thickness, and a sacrificial layer 54 is formed (FIG. 4 (b)). For deposition of the sacrificial layer 54, electroplating such as electroforming is used.

After formation of the sacrificial layer 54, the photoresist 52 is removed. After removal of the photoresist 52, a resist pattern having a recess 56a is formed by using a new photoresist 56 as shown in FIG. 4 (c). The recess 56a exposes part of the sacrificial layer 54 and is formed in a flat surface shape corresponding to the flat surface shape of the probe tip 20b. Thus, as shown in FIG. 4 (d), by depositing the aforementioned metal material for the probe tip 20b in a similar manner to that for the sacrificial layer 54, the probe tip 20b can be formed to be integral with its portion to be buried in the probe main body 20a.

After formation of the probe tip 20b, the photoresist 56 is removed, and as shown in FIG. 4 (e), a resist pattern having a recess 58a is formed by using a new photoresist 58. The recess 58a exposes the portion of the probe tip 20b to be buried in the probe main body 20a and is formed in a flat surface shape corresponding to the flat surface shape of the probe main body 20a. Thus, by depositing in the recess 58a the aforementioned metal material for the probe main body 20a in a similar manner to that for the sacrificial layer 54, the probe main body 20a can be formed so that the buried portion of the probe tip 20b is buried therein. After formation of the probe main body 20a, the photoresist 58 is removed.

After removal of the photoresist 58, a conductive material 136 such as negative photosensitive polyimide is applied over the silicon crystal substrate 50 by, for example, a spin coat technique with approximately uniform thickness as shown in FIG. 4 (f). This photosensitive conductive material 136 covers all exposed surfaces of the silicon crystal substrate 50 and the probe main body 20a, the probe tip 20b, and the sacrificial layer 54 deposited on the silicon crystal substrate 50.

The photosensitive conductive material 136 is selectively exposed by receiving light irradiation through a photo mask 60 on which a light transmission window 60a is formed as shown in FIG. 4 (g). The transmission window 60a is in a flat surface shape corresponding to the shape of the desired insulating film 36 and is accurately positioned at a position corresponding to the probe tip region 34 of the probe main body 20a.

Accordingly, with use of the negative photosensitive conductive material 136, a portion exposed through the transmission window 60a remains as the insulating film 36 by the development process, and the rest is removed. Thus, the insulating film 36 is formed on the probe tip region 34 accurately.

After formation of the insulating film 36, the sacrificial layer 54 is removed by an etching process, and the finished probe 20 is detached from the silicon crystal substrate 50. This detached probe 20 is fixed to the probe board 18 at the attachment end portion 28a of the probe main body 20a with Pb-free solder as described above. At this moment, since the insulating film 36 never covers the attachment end portion 28a, this insulating film 36 will not disturb the fixing work with the solder. Thus, the probe 20 can be fixed firmly to the probe board 18 by soldering.

Although, in the foregoing description, an example in which only the probe tip region 34 is covered with the insulating film 36 has been shown, the entire area on one surface of the probe main body 20a except the attachment end portion 28a may be covered with the aforementioned insulating film. Also, the insulating film 36 may be formed on both surfaces of the probe main body 20a. In such cases as well, the attachment end portion 28a can be exposed from the aforementioned insulating film accurately. Thus, the attachment work of the probe 20 to the probe board 18 will not be disturbed by the insulating film, and the probe 20 can be fixed firmly to the probe board 18.

The present invention is not limited to the above embodiments but may be altered in various ways without departing from the spirit and scope of the present invention. For example, although an example in which the probe tip is made of a different metal material from that for the probe main body has been shown, the probe tip may be formed integrally with the probe main body with the metal material for the probe main body.

What is claimed is:

1. A probe comprising:
a probe main body made of a plate-shaped member having an attachment region having an attachment end portion and extending in a direction distanced from said attachment end portion, an arm region continuing into said attachment region and extending in a direction intersecting with the extending direction of said attachment region, and a probe tip region intersecting with the longitudinal direction of said arm region, extending from said arm region to the opposite side of a side where said attachment end portion of said attachment region is located, seen from said arm portion, and having a probe tip at its extending end portion,
wherein an insulating film made of a photosensitive electrically insulating material that exposes said attachment end portion of said attachment region is formed on at least one surface of said probe main body.

2. The probe according to claim 1, wherein conductive adhesive is applied to said attachment end portion.

3. The probe according to claim 1, wherein said insulating film is formed at said probe tip region on said one surface of said probe main body.

4. The probe according to claim 1, wherein said insulating film is formed by forming a resist pattern having a recess corresponding to a desired flat surface shape of said probe main body on a base table by utilizing photolithography, depositing a probe material in said recess to form said each region of said probe main body, thereafter covering all areas of said regions with a photosensitive electrically insulating material, and selectively leaving a desired portion of said photosensitive electrically insulating material by selective exposure and development processing of said photosensitive electrically insulating material.

5. A probe assembly comprising:
a probe board provided with a plurality of conductive paths; and
a probe including a probe main body made of a plate-shaped member having an attachment region having an attachment end portion to be attached to said corresponding conductive path of said probe board and extending in a direction distanced from said attachment end portion, an arm region continuing into said attachment region and extending in a direction intersecting with the extending direction of said attachment region, and a probe tip region intersecting with the longitudinal direction of said arm region, extending from said arm region to the opposite side of a side where said attachment end portion of said attachment region is located, seen from said arm portion, and having a probe tip at its extending end portion,
wherein said probe is attached to said probe board with one surface of its probe main body opposed to each other, and on at least either of the opposed surfaces of said probe main bodies is formed an insulating film made of a photosensitive electrically insulating material that exposes said attachment end portion of said attachment region.

6. The probe assembly according to claim 5, wherein to said attachment end portion of said attachment region of said probe main body is applied Pb-free solder for fixing said probe at said attachment end portion on a probe land formed on said conductive path of said probe board.

7. The probe assembly according to claim 5, wherein said insulating film is formed at said probe tip region on said one surface of said probe main body.

8. The probe assembly according to claim 5, wherein said insulating film is formed by forming a resist pattern having a recess corresponding to a desired flat surface shape of said probe main body on a base table by utilizing photolithography, depositing a probe material in said recess to form said each region of said probe main body, thereafter covering all areas of said regions with a photosensitive electrically insulating material, and selectively leaving a desired portion of said photosensitive electrically insulating material by selective exposure and development processing of said photosensitive electrically insulating material.
